(19) United States
(12) Patent Application Publication
(10) Pub. No.: US 2004/0106260 A1
(43) Pub. Date: Jun. 3, 2004

(54) Process of utilizing CF4 plasma pretreatment to improve high-k dielectric materials

(76) Inventors: Tan Fu Lei, Hsinchu (TW); Tzu Yun Chang, Hsinchu (TW); Hsiao Wei Chen, Hualien City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/358,293

(22) Filed: Feb. 5, 2003

(30) Foreign Application Priority Data
Nov. 28, 2002 (TW) 91134760

(51) Int. Cl. H01L 21/31; H01L 21/3205; H01L 21/336; H01L 21/469; H01L 21/4763

(52) U.S. Cl. 438/287; 438/591; 438/785

(57) ABSTRACT

The invention provides a process of utilizing CF₄ plasma pretreatment to improve high-k dielectric materials. The process is performed by the standard complimentary metal-oxide-semiconductor field enhanced transistor (CMOSFET) in accordance with the high-k dielectric materials, in which CF₄ plasma generated by plasma enhanced chemical vapor deposition (PECVD) is used to perform pretreatment on the silicon substrate, and a large amount of fluorine will be incorporated on the surface of silicon substrate. Then, a gate dielectric layer is deposited on the surface of silicon substrate, and a thermal annealing in an oxygen ambience is performed. At this time, the silicon substrate incorporating with fluorine will not respond to the high-k dielectric materials to form silicate; therefore, the property of silicon substrate can be improved. The advantages of high-k dielectric materials formed by the process include low leakage current, high breakdown voltage, and good reliability.

### BACKGROUND OF THE INVENTION

1. Field of the Invention

The invention relates to a semiconductor process that can improve high-k dielectric materials and, more particularly, to a process of utilizing CF₄ plasma pretreatment to improve high-k dielectric materials.

2. Description of the Related Art

When the producing of semiconductor devices proceeds to deep sub-micron regime, the integrated densities of integrated circuits will become higher, whereas the sizes of devices will become smaller. The future semiconductor devices will tend to be smaller in size and lower in resistance to reach faster speed. Therefore, the metal gates will take the place of polysilicon gates and, similarly, the high-k dielectric materials will take the place of gate oxide layer of SiO₂ eventually.

The gate oxide layer has to be formed under low temperature because it is subjected to the processing of metal gates. However, the low-temperature gate oxide layer has a lot of defects residing in the interface between the silicon substrate and the oxide layer, which will increase leakage current and, therefore, diminish the reliability. As to high-k dielectric materials such as TiO₂, the interfacial layer formed between the silicon substrate and the high-k dielectric materials will lower the dielectric constant, increase the defects of interface, and subsequently diminish the reliability.

Furthermore, the high-k dielectric materials can be applied to the complimentary metal-oxide-semiconductor field enhanced transistor (CMOSFET) as gate dielectric materials. However, the silicate interfacial layer formed between the high-k dielectric materials and the silicon substrate will deteriorate the characteristics of gate dielectric layer. To solve the problem, the conventional processing of high-k dielectric materials is first to form a barrier layer 12 on the surface of silicon substrate 10, as shown in FIG. 1. Then, a high-k dielectric layer 14 is formed on the surface of barrier layer 12, and a gate structure 16 is formed on the upper side of the barrier layer 12 so that the barrier layer 12 can be used to suppress the formation of silicate interfacial layer. However, the formation of barrier layer 12 is not easy, and the existence of barrier layer 12 will lower the dielectric constant.

Therefore, focusing on the above problems, the invention provides a process of utilizing CF₄ plasma pretreatment to improve high-k dielectric materials so that the high-k dielectric constant can be maintained as well as the quality of gate dielectric layer can be enhanced.

### SUMMARY OF THE INVENTION

The object of the invention is to provide a process of utilizing CF₄ plasma pretreatment to improve high-k dielectric materials. The process utilizes CF₄ plasma to perform pretreatment on the surface of silicon substrate so that the formation of silicate between the high-k dielectric layer and the silicon substrate can be suppressed, and the quality of interface can be enhanced as well.

Another object of the invention is to provide a process of utilizing CF₄ plasma pretreatment to improve the property of high-k dielectric materials so that the formed high-k dielectric materials have low leakage current, high breakdown voltage, and good reliability to ensure the electrical quality of devices.

To achieve the above objects, the process of the invention is first to provide a conductive type silicon substrate. The next step is to perform pretreatment on the silicon substrate by CF₄ Plasma generated by the plasma enhanced chemical vapor deposition (PECVD), and through the pretreatment, a large amount of fluorine will be incorporated on the silicon surface. After that, a high-k gate dielectric layer is deposited on the surface of the treated silicon substrate. Finally, the high-k gate dielectric layer is processed with a thermal annealing in an oxygen ambience.

The objects and technical contents of the invention will be better understood through the description of the following embodiments with reference to the drawings.

### BRIEF DESCRIPTION OF THE DRAWINGS

FIG. 1 is a sectional view showing the formation of a conventional high-k dielectric layer.

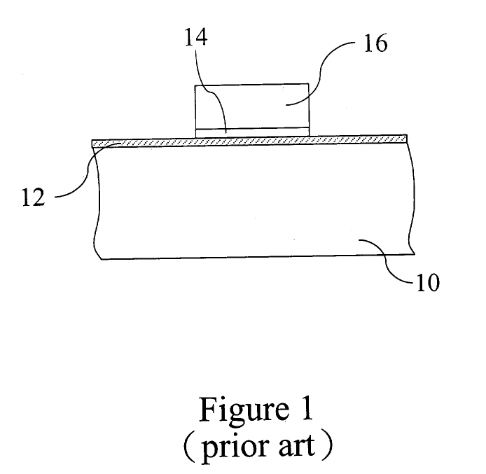

FIG. 2 is a schematic flow chart showing process flow of the invention.

FIG. 3 is a diagram of two curves showing I-V characteristics of TiO₂ processed by the conventional technique and the technique of the invention.

FIG. 4 is a distributive diagram showing leakage current of TiO₂ processed by the conventional technique and the technique of the invention.

FIG. 5 is a distributive diagram showing breakdown charge of TiO₂ processed by the conventional technique and the technique of the invention.

### DESCRIPTION OF THE PREFERRED EMBODIMENTS

The invention utilizes CF₄ plasma to perform pretreatment on the surface of silicon substrate in order to suppress the interfacial layer formed between the high-k dielectric materials (gate dielectric layer) and the silicon substrate effectively, and further to enhance the quality of interface between the high-k dielectric materials and the silicon substrate.

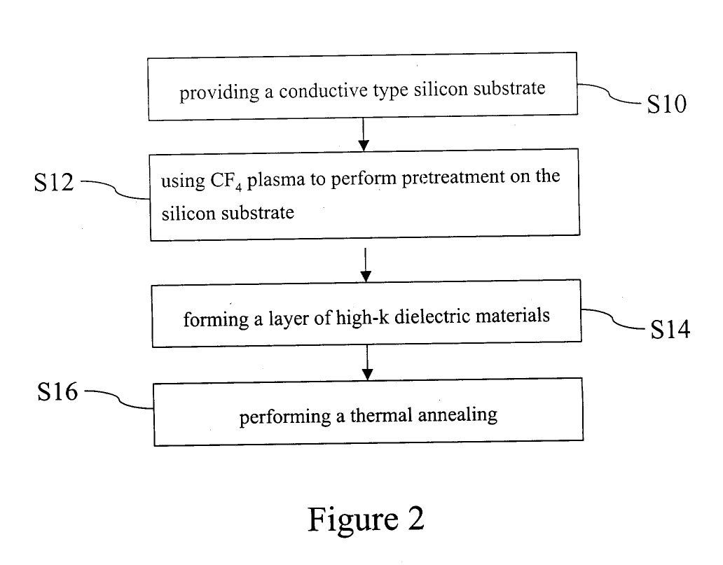

FIG. 2 is a schematic flow chart showing process flow of the invention. As shown in FIG. 2, a process of utilizing CF₄ plasma pretreatment to enhance the quality of high-k dielectric materials includes the following steps. First, as shown in step S10, a silicon substrate is provided, which is a conductive type silicon wafer. Second, as shown in step S12, CF₄ plasma generated by the plasma enhanced chemical vapor deposition (PECVD) or the high-density PECVD performs pretreatment on the silicon substrate, and a large amount of fluorine will be incorporated on the surface of silicon substrate. In the step of utilizing CF₄ plasma to perform pretreatment on the silicon substrate, the processing environment is under an ambience of low temperature and low pressure, and the RF power is between 5 and 50 watts so as to generate CF₄ plasma. The range of low temperature is between 25 degrees and 400 degrees Celsius, whereas the range of low pressure is between 100 and 1000 mT.

Third, as shown in step S12, after the step of CF₄ plasma pretreatment is finished, the procedure moves onto step S14. A layer of high-k dielectric materials is deposited on the surface of silicon substrate after the pretreatment. The high-k dielectric materials are used as gate dielectric layer that is formed by using E-gun evaporating to directly process high-k dielectric material powder, wherein the material for high-k dielectric materials can be TiO₂, Al₂O₃, HfO₂, ZrO₂, or CeO₂. Taking TiO₂ as an example, if TiO₂ of high-k dielectric materials is to be formed, the E-gun evaporator can be used to directly process the powder of TiO₂ so as to generate deposition of TiO₂.

Finally, as shown in step S16, the thermal annealing in an oxygen ambience is performed on the high-k gate dielectric layer. By doing so, the surface of silicon substrate incorporating with a lot of fluorine will not respond to the high-k dielectric materials to generate silicate; that is, the silicate interfacial layer will not be generated between the silicon substrate and the high-k dielectric materials. Therefore, the electrical quality can be ensured, and the subsequent process of producing devices such as gate electrodes on the silicon substrate can be continued so as to complete the process of manufacturing transistors.

The spirit of the invention has been fully explained through the above description. The following is a preferred embodiment to verify the foregoing contents and their effectiveness as well as to be fully understood by those who are skilled in the art in order to facilitate their implementations.

First, an experiment group of the invention and a control group of the conventional technique will carry out an experiment comparison in order to compare I-V characteristics, leakage currents, and breakdown voltages between the two groups. The experiment group of the invention utilizes the system of PECVD, the energy of 5-watt RF power, the CF₄ vapor of 20 sccm flow, and the ambience with 300-degree-Celsius low temperature and 600-mT low pressure to perform pretreatment on a silicon wafer for 30 seconds by CF₄ plasma. After the pretreatment, a layer of TiO₂ is deposited on the silicon wafer. On the other hand, the conventional control group is to directly deposit a layer of TiO₂ on the silicon wafer without pretreatment. Then, various experiments such as I-V characteristics, leakage currents, and breakdown voltages are performed on both the experiment group and the conventional control group.

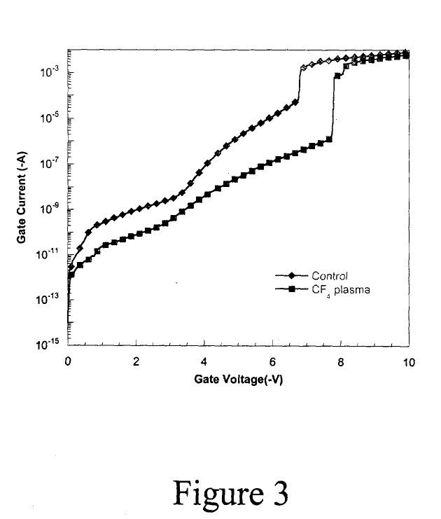

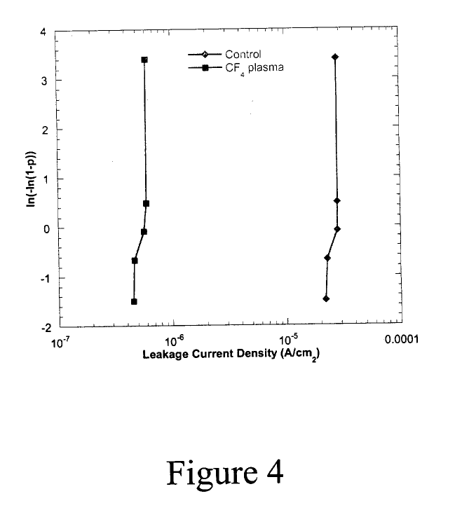

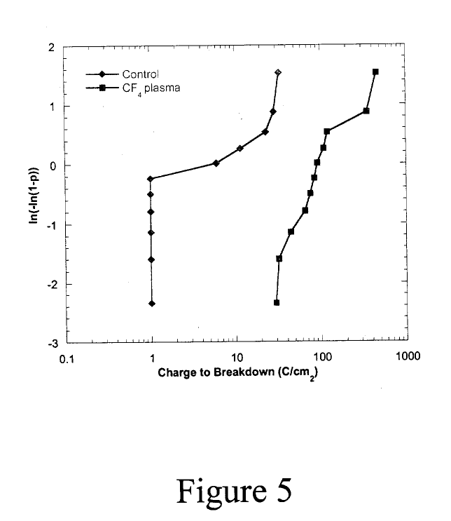

Referring to FIGS. 3, 4, and 5, the result of the experiment can be found in these figures. First, the two curves in FIG. 3 are showing different I-V characteristics of TiO₂ processed by two different methods. As shown in FIG. 3, the I-V characteristics of TiO₂ in the experiment group that has been processed by CF₄ plasma obviously is better than the I-V characteristics of TiO₂ without pretreatment in the control group, which means that the I-V characteristics of TiO₂ formed in the experiment group has been enhanced. With regard to leakage current, as shown in FIG. 4, the distribution range of leakage current of TiO₂ that has been processed by CF₄ plasma in the experiment group is smaller than that of without pretreatment in the control group, which means that TiO₂ formed in the experiment group has low leakage current. Finally, as to breakdown voltage, the experiment result is shown in FIG. 5. As shown in the distributive diagram of breakdown charge, the breakdown voltage processed by CF₄ plasma in the experiment group is higher than that of without pretreatment in the control group; therefore, breakdown voltage in the experiment group is higher. In conclusion, the above experiment result can prove that TiO₂ formed in the invention has good I-V characteristics, low leakage current, and high breakdown voltage.

The invention provides CF₄ plasma pretreatment on the silicon substrate and, after that, a low-temperature process of high-k gate dielectric layer (gate oxide layer) is performed to mend the incomplete bonding of the interface between silicon substrate and high-k dielectric materials by using the energy of fluorine in CF₄ plasma and to further reduce defects in the interface. Moreover, CF₄ plasma has a function of etching; therefore, it can be used to remove the interfacial layer of high-k dielectric materials when it is properly controlled so that the property of high-k dielectric materials can be enhanced.

To sum up, the invention utilizes CF₄ plasma to perform pretreatment on the surface of silicon substrate in order to improve the property of high-k dielectric materials. Therefore, the high-k dielectric materials (i.e. gate dielectric layer) using such processing method have the advantages of low leakage current, high breakdown voltage, and good reliability. Consequently, the electrical quality of devices can be maintained effectively.

The specific embodiment above is only intended to illustrate the invention; it does not, however, to limit the invention to the specific embodiments. Accordingly, those who are skilled in the art can make various modifications and changes without departing from the spirit and scope of the invention as described in the appended claims.

What is claimed is:

1. A process of utilizing CF₄ plasma pretreatment to improve high-k dielectric materials, including the following steps:
providing a silicon substrate;
utilizing CF₄ plasma to perform pretreatment on the silicon substrate, and a large amount of fluorine is incorporated on the surface of silicon substrate;
a gate dielectric layer is formed on the surface of silicon substrate after the pretreatment, and a thermal annealing is performed on the gate dielectric layer.

2. The process of utilizing CF₄ plasma pretreatment to improve high-k dielectric materials as claimed in claim 1, wherein after the thermal annealing, the subsequent process of fabricating devices such as gate electrodes can be continued on the silicon substrate.

3. The process of utilizing CF₄ plasma pretreatment to improve high-k dielectric materials as claimed in claim 1, wherein the silicon substrate is a conductive type silicon wafer.

4. The process of utilizing CF₄ plasma pretreatment to improve high-k dielectric materials as claimed in claim 1, wherein the plasma enhanced chemical vapor deposition (PECVD) or the high-density PECVD is used to generate the CF₄ plasma.

5. The process of utilizing CF₄ plasma pretreatment to improve high-k dielectric materials as claimed in claim 1, wherein the environment for CF₄ plasma pretreatment is under an ambience of low temperature and low pressure, and the RF power is between 5 and 50 watts so as to generate CF₄ plasma.

6. The process of utilizing CF₄ plasma pretreatment to improve high-k dielectric materials as claimed in claim 5, wherein the temperature of CF₄ plasma pretreatment is between 25 and 400 degrees Celsius.

7. The process of utilizing CF₄ plasma pretreatment to improve high-k dielectric materials as claimed in claim 5, wherein the pressure of the CF₄ plasma pretreatment is between 100 and 1000 mT.

8. The process of utilizing CF₄ plasma pretreatment to improve high-k dielectric materials as claimed in claim 1, wherein the material of the high-k gate dielectric layer is selected from a group of high-k dielectric materials, including TiO₂, Al₂O₃, HfO₂, ZrO₂, and CeO₂.

9. The process of utilizing CF₄ plasma pretreatment to improve high-k dielectric materials as claimed in claim 1, wherein the method of forming the high-k gate dielectric layer is to utilize E-gun evaporating system to directly process high-k dielectric material powder.

10. The process of utilizing CF₄ plasma pretreatment to improve high-k dielectric materials as claimed in claim 1, wherein in the step of thermal annealing, the thermal annealing is processed in an oxygen ambience.
